(19) United States
(12) Patent Application Publication
(10) Pub. No.: US 2026/0032984 A1
(43) Pub. Date: Jan. 29, 2026

(54) TRENCH BASED SEMICONDUCTOR DEVICES WITH CONFORMAL SALICIDE THICKNESS

(71) Applicant: Wolfspeed, Inc., Durham, NC (US)

(72) Inventors: Rahul R. Potera, Apex, NC (US); Shadi Sabri, Apex, NC (US); Yao Qian, Durham, NC (US); Neal Oldham, Apex, NC (US); Steven Rogers, Stem, NC (US)

(21) Appl. No.: 18/781,526

(22) Filed: Jul. 23, 2024

(51) Int. Cl. H01L 29/49; H01L 21/28; H01L 21/768; H01L 29/16; H01L 29/45; H01L 29/66; H01L 29/808

(52) U.S. Cl. CPC H10D 64/668; H01L 21/28176; H01L 21/76816; H10D 12/031; H10D 62/8325; H10D 30/0515; H10D 30/6737; H10D 30/6743; H10D 30/831

(57) ABSTRACT

A semiconductor device includes a semiconductor layer including a trench, wherein the trench is adjacent a mesa, a first metal silicide layer on a top portion of the mesa, and a second metal silicide layer on a bottom portion of the trench. The first metal silicide layer has a thickness that is no more than about 1 to 1.5 times greater than a thickness of the second metal silicide layer. Related methods of forming a semiconductor device are disclosed.

### TECHNICAL FIELD

The present disclosure relates to semiconductor devices and, more particularly, to power semiconductor devices having gate resistors.

### BACKGROUND

A wide variety of power semiconductor devices are known in the art including, for example, power Junction Field Effect Transistors (“JFETs”), power Metal Oxide Semiconductor Field Effect Transistors (“MOSFETs”), Insulated Gate Bipolar Transistors (“IGBTs”) and various other devices. These power semiconductor devices are often fabricated from wide bandgap semiconductor materials. Herein, the term “wide bandgap semiconductor” encompasses any semiconductor having a bandgap of at least 1.4 eV. Power semiconductor devices are designed to selectively block or pass large voltages and/or currents. For example, in the blocking state, a power semiconductor device may be designed to sustain hundreds or thousands of volts of electric potential.

Power semiconductor devices having high power ratings are most typically fabricated using silicon carbide, as silicon carbide has a number of advantageous characteristics including, for example, a high electric field breakdown strength, high thermal conductivity, high electron mobility, high melting point and high-saturated electron drift velocity. A conventional silicon carbide-based power semiconductor device typically has a silicon carbide substrate, such as a silicon carbide wafer having a first conductivity type (e.g., an n-type substrate), on which a silicon carbide epitaxial layer structure is formed which may have both first and second conductivity type layers and/or regions. Herein, the terms “first conductivity type” and “second conductivity type” are used to indicate either n-type or p-type, where the first and second conductivity types are different. Thus, if a first region of a device has a first conductivity type and a second region of the device has a second conductivity type, this means either that the first region has n-type conductivity and the second region has p-type conductivity or, alternatively, that first region has p-type conductivity and the second region has n-type conductivity.

The epitaxial layer structure of most power semiconductor devices includes a drift region and an “active region” that is formed on and/or in the drift region. The active region acts as a main junction for blocking voltage during off-state operation (also referred to as “reverse bias” or “reverse blocking” operation) and current flows through the active region during on-state operation (also referred to as “forward bias” operation). Most power semiconductor devices also have an edge termination region adjacent the active region. The edge termination region is designed to spread the electric fields during reverse blocking operation out over a greater area in order to reduce electric field crowding effects that would otherwise occur along the outer edges of the active region. One or more power semiconductor devices may be formed on the wafer, and each power semiconductor device will typically have its own edge termination region. After the epitaxial layer(s) is/are grown on the wafer and fully processed, the wafer may be diced to separate the individual edge-terminated power semiconductor devices if multiple devices are formed on the same wafer (or other substrate). The power semiconductor devices may have a unit cell structure in which the active region of each power semiconductor device includes a large number of individual cells that are disposed in parallel to each other and that together function as a single power semiconductor device.

A vertical JFET is a three terminal device that has gate, drain and source terminals that are formed on a semiconductor layer structure, which typically comprises a semiconductor substrate with epitaxial layers formed thereon. Source regions that are electrically connected to the source terminal and a drain region that is electrically connected to the drain terminal may be formed in the semiconductor layer structure. A plurality of channel regions are interposed in the semiconductor layer structure between the source regions and the drain region. A gate structure of the vertical JFET may include, for example, a gate bond pad that serves as the gate terminal, a gate pad that is connected to the gate bond pad, a plurality of gate contacts, and one or more gate buses and/or gate contacts that electrically connect the gate pad to the gate contacts. The gate contacts are disposed adjacent the respective channel regions. Power JFETs are typically normally-on devices, meaning that a JFET conducts current when a voltage of 0 volts is applied to the gate structure.

### SUMMARY

A method of forming a semiconductor device according to some embodiments includes forming a trench in a semiconductor layer, wherein the trench is adjacent a mesa and the semiconductor layer includes silicon, depositing metal on the semiconductor layer, wherein the metal forms a first metal layer on a top portion of the mesa and a second metal layer on a bottom portion of the trench, and annealing the semiconductor layer so that the first metal layer and the second metal layer form a respective first metal silicide layer on the top portion of the mesa and a second metal silicide layer on the bottom portion of the trench. Annealing the semiconductor layer is performed for an anneal time and/or at an anneal temperature that are selected so that the second metal layer is fully silicided during the annealing while the first metal layer is only partially silicided during the annealing. The method further includes removing un-silicided portions of the first metal layer.

The metal may include nickel and the semiconductor layer may include silicon carbide.

The first metal layer may have a thickness as deposited of about 100 nm or greater and the second metal layer may have a thickness as deposited of about 50 nm or less.

The first metal layer may have a thickness as deposited of about two or more times greater than a thickness of the second metal layer as deposited.

The first metal silicide layer may have a thickness of about 100 nm or greater and the second metal silicide layer may have a thickness of about 100 nm or less.

The first metal silicide layer may have a first thickness that is less than about 2 times a second thickness of the second metal silicide layer. In some embodiments, the first metal silicide layer may have a first thickness that is about 1 to 1.5 times greater than a second thickness of the second metal silicide layer.

The first metal silicide layer may have a first thickness of less than about twice a second thickness of the first metal layer.

The trench may have an aspect ratio of about 1.5:1 or greater.

Annealing the semiconductor layer may be performed at an anneal temperature of less than about 650′C and/or for an anneal time of less than about 150 seconds.

A semiconductor device according to some embodiment includes a semiconductor layer including a trench, wherein the trench is adjacent a mesa, a first metal silicide layer on a top portion of the mesa, and a second metal silicide layer on a bottom portion of the trench. The first metal silicide layer has a thickness that is less than about 2 times greater than a thickness of the second metal silicide layer, and in some embodiments no more than about 1 to 1.5 times greater than the thickness of the second metal silicide layer.

The metal may include nickel and the semiconductor layer includes silicon carbide.

The first metal layer may have a thickness as deposited of about 100 nm or greater and the second metal layer may have a thickness as deposited of about 50 nm or less.

The first metal layer may have a thickness as deposited of about two or more times greater than a thickness of the second metal layer as deposited.

The first metal silicide layer may have a thickness or about 100 nm or greater and the second metal silicide layer may have a thickness of about 100 nm or less.

The first metal silicide layer may have a thickness of less than about twice a thickness of the first metal layer.

The trench may have an aspect ratio of about 1.5:1 or greater.

A method of forming a semiconductor device according to further embodiments includes forming a trench in a semiconductor layer, wherein the trench is adjacent a mesa and the semiconductor layer includes silicon, depositing metal on the semiconductor layer, wherein the metal forms a first metal layer on a top portion of the mesa and a second metal layer on a bottom portion of the trench, partially siliciding the first metal layer while fully siliciding the second metal layer to form a first metal silicide layer on the top portion of the mesa and a second metal silicide layer on the bottom portion of the trench, and removing un-silicided portions of the first metal layer.

Partially siliciding the first metal layer while fully siliciding the second metal layer may include annealing the semiconductor layer for an anneal time and/or at an anneal temperature that are selected so that the second metal layer is fully silicided during the annealing while the first metal layer is only partially silicided during the annealing.

The metal may include nickel and the semiconductor layer includes silicon carbide.

### BRIEF DESCRIPTION OF DRAWINGS

FIG. 1 illustrates a cell of a vertical JFET semiconductor device.

FIGS. 2A and 2B illustrate, in plan view, conventional layouts of vertical JFET semiconductor devices.

FIGS. 3A, 3B and 3C illustrate a general metal silicidation process.

FIGS. 4A, 4B and 4C illustrate a conventional silicidation process for forming source and gate ohmic contacts on a vertical semiconductor device.

FIGS. 5A, 5B and 5C illustrate a silicidation process according to some embodiments for forming source and gate ohmic contacts on a vertical semiconductor device.

FIG. 6 illustrates operations for forming source and gate ohmic contacts on a vertical semiconductor device according to some embodiments.

### DETAILED DESCRIPTION

Embodiments of the inventive concepts are explained more fully with reference to the non-limiting aspects and examples that are described and/or illustrated in the accompanying drawings and detailed in the following description. It should be noted that the features illustrated in the drawings are not necessarily drawn to scale, and features of some embodiments may be employed with other aspects as the skilled artisan would recognize, even if not explicitly stated herein. Descriptions of well-known components and processing techniques may be omitted so as to not unnecessarily obscure the aspects of the disclosure. The examples used herein are intended merely to facilitate an understanding of ways in which the disclosure may be practiced and to further enable those of skill in the art to practice the aspects of the disclosure. Accordingly, the examples and aspects herein should not be construed as limiting the scope of the disclosure, which is defined solely by the appended claims and applicable law. Moreover, it is noted that like reference numerals represent similar parts throughout the several views of the drawings.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the another element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the another element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art.

Although a JFET device is sometimes referred to as a static induction transistor, the term JFET will be used in the description below. However, it will be appreciated that embodiments described herein may be applied to any device that uses a depletion region to modulate the conductivity of a channel in a mesa.

Although some embodiments are described in the context of a silicon carbide JFET device, it will be appreciated that aspects of the inventive concepts may be applicable to other types of devices, such as MOSFETs, insulated gate bipolar transistors (IGBTs) and other types of devices.

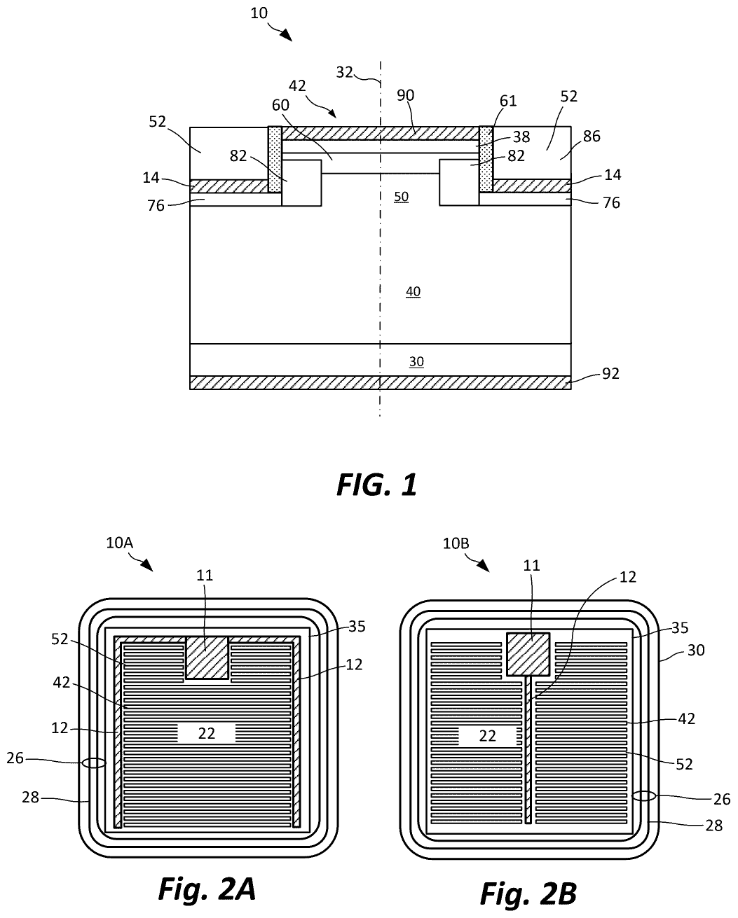

An n-channel vertical JFET structure 10 is shown in FIG. 1. The vertical JFET structure 1 includes an n+ substrate 30 on which an n− drift layer 40 is formed. An n-type channel region 50 is on the drift layer 40, and an n+ source layer 60 is on the channel region 50. An n++ source contact layer 38 is on the n+ source layer 60. A drain ohmic contact 92 is on the substrate 30, and a source ohmic contact 90 is on the source contact layer 38. The channel region 50, source layer 60 and source contact layer 38 are provided as part of a mesa stripe 42 above the drift layer 40. Trenches 52 are formed in the structure 10 adjacent the mesa stripe 42.

A p+ gate region 82 is provided as part of the mesa stripe 42 adjacent the channel region 50. A p++ gate contact region 76 is provided adjacent the gate region 82, and a gate ohmic contact, or gate finger, 14 is formed on the gate contact region 76 in the trenches 52 on opposite sides of the mesa stripe 42. To form the gate ohmic contact 14, a layer of metal, such as nickel (Ni), is deposited on the upper surfaces of the gate contact regions 76 and patterned appropriately. The metal is then annealed (for example, by being subjected to high temperature for a period of time) to form metal silicide layers on the upper surfaces of the gate contact regions 76, which provide ohmic contacts to the underlying layers.

An insulation layer 86 is formed in the trenches 52 on the gate finger 14 and the gate contact region 76. The insulation layer 86 may be formed from silicon oxide. Oxide/nitride spacer layers 61 are provided on sidewalls of the mesa stripe 42.

The vertical JFET unit cell structure 10 is symmetrical about the axis 32 and includes two gate regions 82 as part of the mesa stripe 42 on opposite sides of the channel region 50.

The channel of the vertical JFET structure 10 is formed within the mesa stripe 42 between the gate regions 82. The channel width is into the plane of FIG. 1, and the channel length is in the vertical direction from the source region 60 to the drift layer 40. Such a vertical JFET structure with a short channel length may also be called a static-induction transistor (SIT). In a SIT, the channel length is chosen based on a trade-off between low on-resistance in the on-state (short channel) and resistance to drain-induced barrier lowering (DIBL) in the off-state. A p-channel JFET may have a similar structure, but the conductivity types are reversed from those shown in FIG. 1.

In operation, conductivity between the source layer 60 and the substrate 30 is modulated by applying a reverse bias to the gate regions 82 relative to the source layer 60. To switch off an n-channel device such as the JFET structure 10, a negative gate-to-source voltage (or gate voltage) VGS is applied to the gate regions 82. When no voltage is applied to the gate region 82, charge carriers can flow freely from the source layer 60 through the channel region 50 and the drift layer 40 to the substrate 30.

FIGS. 2(A) and 2(B) illustrate, in plan view, conventional layouts of vertical JFET semiconductor devices 10A and 10B, respectively. Referring to FIG. 2(A), a JFET device 10A is formed on a substrate 30. The device 10A includes an active region 22 in which a plurality of alternating mesa stripes 42 and trenches 52 are formed. The active region 22 is surrounded by an edge termination region 26 in which a plurality of guard rings 28 are formed. Guard rings 28 are shown as an example of an edge termination for a power semiconductor device. However, other termination structures, such as field rings, junction termination extension (JTE) regions, etc., can be provided in the edge termination region 26.

A silicide region 35 is formed on an upper surface of the device within the active region 22 in areas other than on the mesa stripes 42. The silicide region 35 forms the gate ohmic contacts 14 within the trenches 52. A gate contact pad 11 is formed on the upper surface of the device 10A within the silicide region 35, and a pair of gate buses 12 (also referred to as gate runners 12) extend from the gate contact pad 11 around the outer periphery of the active region 22 adjacent the ends of the mesa stripes 42 and trenches 52 of the device 10A. The gate contact pad 11 and the gate buses 12 may include a conductive material such as a metal silicide and/or a metal layer.

The silicide region 35 provides a low resistance current path between the gate buses 12/gate contact pad 11 and the gate ohmic contacts 14 (FIG. 1) that are formed within the trenches 52.

The JFET device 10B shown in FIG. 2(B) is similar to the JFET device 10A shown in FIG. 2(A), except that the JFET device 10B includes only a single gate bus 12 which extends from the gate contact pad 11 through the center of the active region 22.

In both JFET devices 10A, 10B, a gate voltage applied to the gate contact pad 11 is conducted through the gate bus 12 and silicide region 35 to the gate ohmic contacts 14 within the trenches 52.

Referring again to FIG. 1, the gate ohmic contacts 14 and the source ohmic contacts 90 may be formed through a self-aligned silicide process, or “salicide” process. In a salicide process, a silicide layer or region is formed in such a manner that it is self-aligned to the underlying layer or region on which it is formed.

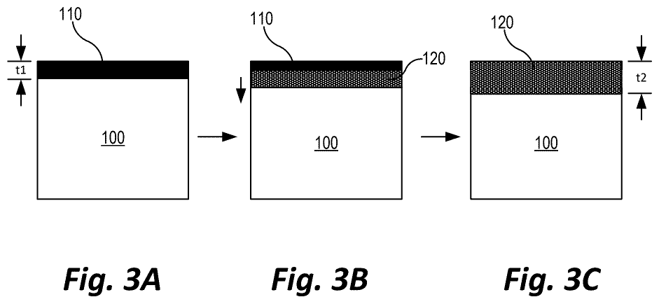

FIG. 3 illustrates the formation of a silicide layer 120 on a layer 100 of a silicon-containing crystalline material, such as crystalline silicon carbide (SiC). Referring to FIG. 3(A), a metal layer 110 is deposited on the silicon-containing layer 100, for example using a deposition process such as sputtering or evaporation. The metal layer 110 has a first thickness t1, and may include a metal such as nickel (Ni).

Referring to FIG. (3B), the structure is then annealed at a temperature sufficient to cause the layer of metal to react with the silicon in the silicon-containing layer 100 to form a layer 120 of metal silicide, such as NiSi. For example, the structure may be annealed at a temperature greater than about 500° C.

As the reaction proceeds, it is believed that upper portions of the silicon-containing layer 100 nearest the metal layer 110 are consumed first by the formation of the metal silicide layer 120, so that the metal silicide layer 120 grows downward into the silicon-containing layer 100.

Similarly, it is believed that portions of the metal layer 110 nearest the silicon-containing layer 100 are consumed first, and portions of the metal layer 110 farthest from the silicon-containing layer 100 are consumed later in the process.

The anneal process proceeds until all of the metal layer 110 has been consumed, leaving only a layer 120 of metal silicide 120 on the silicon-containing layer 100, as shown in FIG. 3(C). The resulting metal silicide layer 120 has a second thickness t2 that is larger than the thickness t1 of the metal layer 110. Although not wishing to be bound by any particular theory of operation, this difference in thickness between the metal layer 110 and the metal silicide layer 120 is believed to occur because the metal silicide layer 120 is composed of all of the metal atoms of the metal layer 110 plus the silicon atoms consumed from the silicon-containing layer 100. In particular, the metal silicide layer 120 may have a final thickness t2 that is about twice the initial thickness t1 of the metal layer 110.

For example, when the silicon-containing layer 100 is silicon carbide and the metal layer 110 is nickel and has an initial thickness t1 of about 50 nm, the metal silicide layer 120 may have a final thickness t2 of about 100 nm.

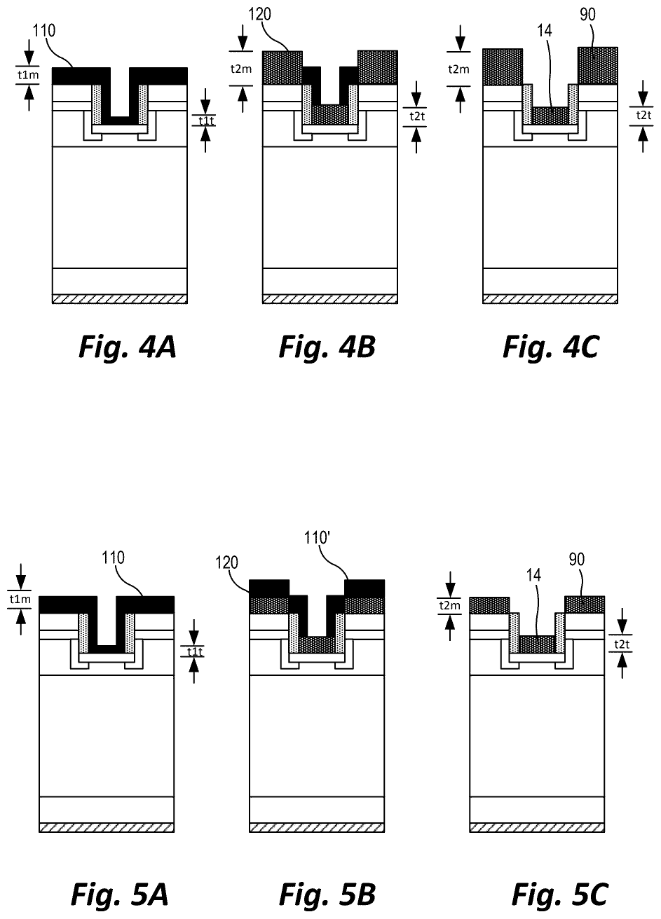

Conventional operation for forming the source ohmic contacts 90 and the gate ohmic contacts 14 in a vertical semiconductor device structure 10 are illustrated in FIG. 4.

Referring to FIG. 4(A), after formation of the epitaxial structure of the device 10 including trenches 52 and mesas 42, a layer 110 of a metal such as nickel is blanket deposited on the structure using a process such as evaporation or sputtering, although any suitable deposition method may be used. In the deposition process, the deposited metal may preferentially accumulate on the top surfaces of the mesas 42, so that the initial thickness t1m of the metal layer 120 on the tops of the mesas 42 is larger than the initial thickness t1t of the metal layer 110 at the bottoms of the trenches 52. For example, when the initial thickness t1m of the metal layer 120 on the tops of the mesas 42 is about 110 nm, the initial thickness t1t of the metal layer 110 at the bottoms of the trenches 52 may only be about 40 nm. Although not wishing to be bound by any particular theory of operation, this is believed to occur due to shadowing by the mesas 42 when the trenches 52 have an aspect ratio of about 1.5:1 or greater.

Referring to FIG. 4(B), after deposition of the metal layer 110, the structure is annealed to cause the metal in the metal layer 110 to react with silicon in at least the source contact layer 38 and the gate contact layer 76 to form a metal silicide layer 120. For example, the structure may be annealed at a temperature of about 630° C. to about 660° C. In some embodiments, the structure may be annealed at a temperature of about 635° C. to about 655° C. In some embodiments, the structure may be annealed at a temperature of about 640° C. to about 650° C.

In some embodiments, the structure may be annealed for about 110 to 150 seconds, in some embodiments for about 120 to 140 seconds, and in some embodiments for about 125 to 135 seconds.

Unsilicided portions of the metal layer 110 are then removed, for example via lift-off process, etching or other suitable removal process, to leave metal silicide only on the source contact layer 38 and the gate contact layer 76 to form the source ohmic contacts 90 and gate ohmic contacts 14, respectively, as shown in FIG. 4(C).

Because the metal in the metal layer 110 is fully consumed in the silicidation process, the metal silicide layer 120 may have a final thickness t2m on the tops of the mesas 42 of at least about twice the initial thickness t1m of the metal layer 110 on the tops of the mesas 42. Thus, when the initial thickness t1m of the metal layer 110 on the tops of the mesas 42 is about 110 nm, the final thickness t2m of the metal silicide layer 120 on the tops of the mesas 42 may be at least about 220 nm.

Similarly, when the initial thickness t1t of the metal layer 110 on the bottom surfaces of the trenches 52 is about 40 nm, the final thickness t2t of the metal silicide layer 120 on the bottom surfaces of the trenches 52 may be at least about 80 nm.

It may be undesirable to have significantly different thicknesses of metal silicide layers forming the source ohmic contacts 90 and the gate ohmic contacts 14 of the device 10.

To obtain source and gate ohmic contacts having roughly similar thicknesses, some embodiments described herein utilize a silicidation anneal time that is low enough to fully silicide the thin nickel at the bottoms of the trenches 52, but not to fully silicide the thicker nickel at tops of the mesas 42. In this manner, a ratio of thickness of the silicide layer at the bottoms of the trenches 52 to the tops of the mesas 42 is increased.

There are several constraints on silicide thicknesses in a JFET structure. For example, as noted above, nickel as sputtered deposits thicker on the mesa top than at trench bottom by a factor of greater than about 2 times. Thus, for example, if 200 nm of nickel is sputter deposited, then about 200 nm is deposited on the mesa top and about 80-100 nm is deposited at the trench bottom.

The silicide at the bottoms of the trenches 52 should be thick enough to have a low sheet resistance, which controls gate resistance of the device. With an 80 nm silicide layer at the bottoms of the trenches 52, a sheet resistance of ˜3-4 ohms/sq may be obtained. A silicide thickness of about 100 nm at the trench bottom is desired to reduce sheet resistance further and reduce gate resistance (Rg).

The silicide layer at the tops of the mesas 42 should be thin enough to limit SiC consumption at mesa top during silicidation. When a silicide layer having a thickness of greater than about 200 nm is formed on the tops of the mesas 42, too much SiC may be consumed from the source contact layer 38. It may therefore be desirable to reduce the silicide thickness on the tops of the mesas 42.

For an initial metal thickness of 110 nm, a silicidation anneal performed at between about 630° C. and 660° C. for about 120 to 140 seconds can fully silicide the metal layer at both the mesa top and trench bottom. According to some embodiments, a silicidation anneal is performed under anneal conditions (e.g., time and/or temperature) such that the entire metal layer on the tops of the mesas 42 is not fully silicided. The resulting metal silicide layer on the mesa top may be less than about 2 times, and in some embodiments only about 1 to 1.5 times, the thickness of metal silicide layer on the bottoms of the trenches 52, rather than twice the thickness as in conventional devices.

Operations according to some embodiments are illustrated in FIG. 5. Referring to FIG. 5(A), after formation of the epitaxial structure of the device 10 including trenches 52 and mesas 42, a layer 110 of a metal such as nickel is blanket deposited on the structure using a process such as deposition or sputtering. In the deposition process, the deposited metal may preferentially accumulate on the top surfaces of the mesas 42, so that the initial thickness t1m of the metal layer 110 on the tops of the mesas 42 is larger than the initial thickness t1t of the metal layer 110 at the bottoms of the trenches 52. For example, when the initial thickness t1m of the metal layer 110 on the tops of the mesas 42 is about 110 nm, the initial thickness t1t of the metal layer 110 at the bottoms of the trenches 52 may only be about 40 nm.

Referring to FIG. 5(B), after deposition of the metal layer 110, the structure is annealed to cause the metal in the metal layer 110 to react with silicon in at least the source contact layer 38 and the gate contact layer 76 to form a metal silicide layer 120. According to some embodiments, the anneal conditions (e.g. anneal time and/or anneal temperature) are chosen so that the portion of the metal layer 110 on the tops of the mesas 42 is only partially silicided. For example, the structure may be annealed at a temperature of about 630° C. to about 660° C. In some embodiments, the structure may be annealed at a temperature of about 635° C. to about 655° C. In some embodiments, the structure may be annealed at a temperature of about 640° C. to about 650° C. In some embodiments, the structure may be annealed for about 110 to 150 seconds, in some embodiments for about 120 to 140 seconds, and in some embodiments for about 125 to 135 seconds.

After the anneal operation, a silicide layer 120 is formed on the mesa tops and trench bottoms while un-silicided portions 110′ of the metal layer 110 remains on the mesa tops.

Referring to FIG. 5(C), the unsilicided portions 110′ of the metal layer 110 are removed, for example using a wet etch or other suitable removal procedure, to leave metal silicide source ohmic contacts 90 on the tops of the mesas 42 and metal silicide gate ohmic contacts 14 in the trenches 52. Because the metal layer 110 on the tops of the mesas 42 was only partially silicided, the metal silicide source ohmic contacts 90 may have a final thickness t2m that is less than twice the thickness of the final thickness t2t of the gate ohmic contacts 14. In some embodiments, the metal silicide source ohmic contacts 90 may have a final thickness t2m that is less than about 2 times, and in some embodiments about 1 to 1.5 times, the thickness of the final thickness t2t of the gate ohmic contacts 14.

For example, when the final thickness t2t of the gate ohmic contacts 14 is about 80 nm, the final thickness t2m of the source ohmic contacts 90 may be about 150 nm or less.

Accordingly, the metal silicide layer that forms the source ohmic contacts 90 on the mesa 42 tops may be made thinner to reduce SiC consumption, while the metal silicide gate ohmic contacts 14 on the trench 52 bottoms are made thicker to obtain low gate resistance.

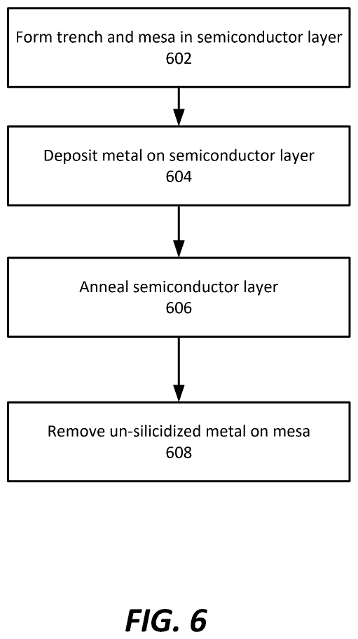

FIG. 6 illustrates operations for forming a semiconductor device according to some embodiments. In particular, a method of forming a semiconductor device according to some embodiments includes forming (602) a trench in a semiconductor layer. The trench is adjacent a mesa and the semiconductor layer includes silicon. The method further includes depositing (604) metal on the semiconductor layer. The metal forms a first metal layer on a top portion of the mesa and a second metal layer on a bottom portion of the trench. The semiconductor layer is annealed (606) so that the first metal layer and the second metal layers form a respective first metal silicide layer on the top portion of the mesa and a second metal silicide layer on the bottom portion of the trench. The anneal is performed for an anneal time and/or at an anneal temperature that are selected so that the second metal layer is fully silicided during the annealing while the first metal layer is only partially silicided during the annealing. Un-silicided portions of the first metal layer are then removed (608).

The inventive concepts have been described above with reference to the accompanying drawings, in which embodiments are shown. The inventive concepts may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout, except where expressly noted.

It will be understood that although the terms first and second are used herein to describe various regions, layers and/or elements, these regions, layers and/or elements should not be limited by these terms. These terms are only used to distinguish one region, layer or element from another region, layer or element. Thus, a first region, layer or element discussed below could be termed a second region, layer or element, and similarly, a second region, layer or element may be termed a first region, layer or element without departing from the scope of the present invention.

Relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if the device in the drawings is turned over, elements described as being on the “lower” side of other elements would then be oriented on “upper” sides of the other elements. The exemplary term “lower” can, therefore, encompass both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The term “in electrically conductive contact” means that two elements are in direct or indirect contact in such a way that electrical current can flow from one element to another. At least part of the connection between the two elements may be electrically resistive.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” “comprising,” “includes” and/or “including,” when used herein, specify the presence of stated features, elements, and/or components, but do not preclude the presence or addition of one or more other features, elements, components, and/or groups thereof.

Embodiments of the inventive concepts are described herein with reference to cross-sectional illustrations that are schematic illustrations. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the invention.

It will be understood that the embodiments disclosed herein can be combined. Thus, features that are pictured and/or described with respect to a first embodiment may likewise be included in a second embodiment, and vice versa.

While the above embodiments are described with reference to particular figures, it is to be understood that some embodiments of the present invention may include additional and/or intervening layers, structures, or elements, and/or particular layers, structures, or elements may be deleted. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

1. A method of forming a semiconductor device, comprising:
forming a trench in a semiconductor layer, wherein the trench is adjacent a mesa and the semiconductor layer comprises silicon;
depositing metal on the semiconductor layer, wherein the metal forms a first metal layer on a top portion of the mesa and a second metal layer on a bottom portion of the trench;
annealing the semiconductor layer so that the first metal layer and the second metal layer form a respective first metal silicide layer on the top portion of the mesa and a second metal silicide layer on the bottom portion of the trench, wherein annealing the semiconductor layer is performed for an anneal time and/or at an anneal temperature that are selected so that the second metal layer is fully silicided during the annealing while the first metal layer is only partially silicided during the annealing; and
removing un-silicided portions of the first metal layer.

2. The method of claim 1, wherein the metal comprises nickel and the semiconductor layer comprises silicon carbide.

3. The method of claim 2, wherein the first metal layer has a thickness as deposited of about 100 nm or greater and the second metal layer has a thickness as deposited of about 50 nm or less.

4. The method of claim 2, wherein the first metal layer has a thickness as deposited of about two or more times greater than a thickness of the second metal layer as deposited.

5. The method of claim 2, wherein the first metal silicide layer has a thickness of about 100 nm or greater and the second metal silicide layer has a thickness of about 100 nm or less.

6. The method of claim 2, wherein the first metal silicide layer has a first thickness that is less than about 2 times a second thickness of the second metal silicide layer.

7. The method of claim 6, wherein the first thickness is about 1 to 1.5 times greater than the second thickness.

8. The method of claim 2, wherein the first metal silicide layer has a first thickness of less than about twice a second thickness of the first metal layer.

9. The method of claim 1, wherein the trench has an aspect ratio of about 1.5:1 or greater.

10. The method of claim 2, wherein annealing the semiconductor layer is performed at an anneal temperature of less than 650′C.

11. The method of claim 2, wherein annealing the semiconductor layer is performed at an anneal time of less than 150 seconds.

12. A semiconductor device, comprising:
a semiconductor layer comprising a trench, wherein the trench is adjacent a mesa;
a first metal silicide layer on a top portion of the mesa; and
a second metal silicide layer on a bottom portion of the trench;
wherein the first metal silicide layer has a thickness that is less than about 2 times a thickness of the second metal silicide layer.

13. The semiconductor device of claim 12, wherein first metal silicide has a thickness that is about 1 to 1.5 times greater than the thickness of the second metal layer.

14. The semiconductor device of claim 12, wherein the metal comprises nickel and the semiconductor layer comprises silicon carbide.

15. The semiconductor device of claim 12, wherein the first metal layer has a thickness as deposited of about 100 nm or greater and the second metal layer has a thickness as deposited of about 50 nm or less.

16. The semiconductor device of claim 12, wherein the first metal layer has a thickness as deposited of about two or more times greater than a thickness of the second metal layer as deposited.

17. The semiconductor device of claim 12, wherein the first metal silicide layer has a thickness or about 100 nm or greater and the second metal silicide layer has a thickness of about 100 nm or less.

18. The semiconductor device of claim 12, wherein the first metal silicide layer has a thickness of less than about twice a thickness of the first metal layer.

19. The semiconductor device of claim 12, wherein the trench has an aspect ratio of about 1.5:1 or greater.

20. A method of forming a semiconductor device, comprising:
forming a trench in a semiconductor layer, wherein the trench is adjacent a mesa and the semiconductor layer comprises silicon;
depositing metal on the semiconductor layer, wherein the metal forms a first metal layer on a top portion of the mesa and a second metal layer on a bottom portion of the trench;
partially siliciding the first metal layer while fully siliciding the second metal layer to form a first metal silicide layer on the top portion of the mesa and a second metal silicide layer on the bottom portion of the trench; and
removing un-silicided portions of the first metal layer.

21. The method of claim 20, wherein partially siliciding the first metal layer while fully siliciding the second metal layer comprises annealing the semiconductor layer for an anneal time and/or at an anneal temperature that are selected so that the second metal layer is fully silicided during the annealing while the first metal layer is only partially silicided during the annealing.

22. The method of claim 20, wherein the metal comprises nickel and the semiconductor layer comprises silicon carbide.
